(19) United States
(12) Patent Application Publication
(10) Pub. No.: US 2006/0054949 A1
(43) Pub. Date: Mar. 16, 2006

(54) Ferroelectric memory and method of manufacturing same

(76) Inventor: Takashi Ichimori, Tokyo (JP)

Correspondence Address: VOLENTINE FRANCOS & WHITT, P.L.L.C., ONE FREEDOM SQUARE, 11951 FREEDOM DRIVE, SUITE 1260, RESTON, VA, 20190, US

(21) Appl. No.: 11/166,168

(22) Filed: Jun. 27, 2005

(30) Foreign Application Priority Data
Sep. 10, 2004 (JP) 2004-263279

(51) Int. Cl. H01L 29/94

(52) U.S. Cl. 257/295

(57) ABSTRACT

A ferroelectric memory which ensures a high reliability without increasing the area of a capacitor, and a method of manufacturing the same. An interlayer film 4 is formed on a semiconductor substrate 1 which has been formed with a circuit including a transistor 2 for storage element selection, and a contact hole is formed through the interlayer insulating film 4 by a plasma etching method using an etching gas including CHF₃. Consequently, the resulting contact hole is formed wider toward the ferroelectric capacitor 10 and narrower toward a diffusion layer 2a of the transistor 2. When an electrically conductive material such as tungsten is filled in the contact hole, a material gas is evenly supplied into the contact hole, thereby preventing a void, called a “seam,” in a central region. Thus, the surface of a cell plug can be finished with a uniform and flat surface, and a ferroelectric capacitor 10 having good characteristics can be formed on the cell plug 20.

### BACKGROUND OF THE INVENTION

1. Field of the Invention

The present invention relates to a laminated ferroelectric memory which uses a ferroelectric capacitor as a storage cell, and a method of manufacturing the same.

2. Description of the Related Art

Laid-open Japanese Patent Applications Nos. 61-256724, 64-49242, and 5-190513 disclose etching techniques which can be used for manufacturing ferroelectric memories.

Here, the ferroelectric memory takes advantage of a phenomenon of a resulting polarization which remains in accordance with the polarity of a voltage applied to a capacitor made of a ferroelectric material such as SBT (strontium bismuth tantalum oxide) or the like, thus performing a non-volatile storage of data.

FIG. 2 is a cross-sectional view schematically showing the structure of a conventional laminated ferroelectric memory.

The laminated ferroelectric memory is has a transistor 2 for selection and an element separation region 3 formed on the surface of a semiconductor substrate 1. An interlayer insulating film 4 is formed over the entire surface of the semiconductor substrate 1 including these transistor 2 and element separation region 3. A ferroelectric capacitor 5, which is a storage element, is further formed on the interlayer insulating film 4. The ferroelectric capacitor 5 has a ferroelectric film 5a sandwiched between a lower laminated electrode 5b including platinum and an upper electrode 5c made of platinum. The lower electrode 5b of the ferroelectric capacitor 5 is connected to a diffusion layer 2a of the transistor 2 through a cell plug 6 made of tungsten and formed in the interlayer insulating film 4.

With the foregoing structure, the cell area can be reduced because the ferroelectric capacitor 5, which is a storage element, is stacked on the transistor 2 for selecting this storage element.

The laminated ferroelectric memory as described above is manufactured through the following steps.

First, in a normal wafer step, a circuit including the transistor 2 and element separation region 3 is formed on the surface of the semiconductor substrate 1, and the interlayer insulating film 4 is formed over the entire surface of the circuit. Then, a contact hole is formed in the interlayer insulating film 4 on the diffusion layer 2a of the transistor 2 for embedding the cell plug 6. The contact hole is formed by normal plasma etching using an etching gas including C₄F₈, resulting in a vertical processing shape having a substantially uniform inner diameter.

Next, a tungsten film is formed on the surface of the interlayer insulating film 4 and within the contact hole using a CVD (Chemical Vapor Deposition) method for embedding the formed contact hole with tungsten which is a material for the plug. After the contact hole is filled with the tungsten and the surface of the interlayer insulating film 4 is covered with the tungsten film, the tungsten film is polished by a CMP (Chemical Mechanical Polish) method to remove the tungsten film on a flat region. This results in exposure of the surface of the interlayer insulating film 4 and the top of the cell plug 6.

Further, an electrically conductive material such as platinum, which will later serve as the lower electrode 5b, is sequentially vapor deposited over the entire surface of the interlayer insulating film 4 embedded with the cell plug 6, and an SBT layer, which will later serve as the ferroelectric film 5a, is formed on the surface of the platinum film. Subsequently, the resulting product is thermally treated in an oxygen atmosphere at temperatures of 700 to 700° C. for crystallizing the SBT layer. Then, a platinum film, which will later serve as the upper electrode 5c, is vapor deposited on the surface of the crystallized SBT layer.

Subsequently, the SBT layer, the platinum layers sandwiching the SBT layer, and the like are patterned into separate ferroelectric capacitors 5 corresponding to the respective cell plugs 6. An additional heat treatment is performed for recovering the ferroelectric capacitors 5 from damages applied thereto from a lateral direction during the patterning. This heat treatment is performed under conditions similar to those for the heat treatment for crystallizing the SBT layer.

When the tungsten, the material of the cell plug 6, is exposed to oxygen at high temperatures during the heat treatment, tungsten oxide is formed to cause a defective shape due to an inflated volume and a degraded conductivity. It is therefore necessary to form the platinum layer and the like, which will later serve as the lower electrode 5b to have a predetermined thickness and avoid damages such as crack and fracture in order to prevent heated oxygen from diffusing into the cell plug 6 during the heat treatment.

FIGS. 3(a) to 3(c) are explanatory diagrams for explaining problems of the conventional laminated ferroelectric memory.

As shown in FIG. 3(a), when tungsten, which is the material of the cell plug 6, is embedded in the contact hole formed in a vertical shape having a substantially uniform inner diameter using a CVD method, a generator gas is not sufficiently supplied to a central region of the contact hole. This causes a minute void 6s called “seam” to occur in the vertical direction in the central region of the contact hole. When the surface is subsequently polished by a CMP method to remove a tungsten film 6a on a flat region, the void 6s appears as an opening of the seam at the center of the top of the cell plug 6 as shown in FIG. 3(b). When a platinum film and the like, which will later serve as a lower electrode 5b, are formed on the surface of the cell plug 6 having such an opening, the film formed on the seam region will not be uniform in shape, as shown in FIG. 3(c). Thus, the platinum film on the seam region differs from the platinum film on the flat region in the characteristics such as thickness, step coverage, and crystallinity, and can be cracked in the vertical direction. Consequently, the reliability can be degraded due to the lack of oxidization preventing capabilities for the cell plug 6, which should be essentially required for the platinum film and the like which will later serve as the lower electrode 5b.

Also, when the platinum film and the like, which will later serve as the lower electrode 5b, are formed in a larger thickness in order to compensate for the degraded oxidization preventing capabilities due to the seam, the thickness of the overall ferroelectric capacitor 5 will be increased, as shown in FIG. 2, leading to a higher susceptibility to a degradation in the ease of processing and the shape. Specifically, while a processed surface (side surface) of the ferroelectric capacitor 5 is preferably perpendicular to the semiconductor substrate 1, difficulties in processing the ferroelectric material result in a trapezoidal cross-section which gradually extends from the upper electrode 5c to the lower electrode 5b. In this event, since the base of the trapezoid has a definite area, a larger height of the trapezoid will cause the area of the upper electrode 5c to be smaller, resulting in a reduction in the capacitance of the capacity. Therefore, since the capacitance of the capacitor is reduced when the lower electrode 5b is formed thick, the dimensions of the capacitor must be increased in order to ensure a predetermined capacitance.

### SUMMARY OF THE INVENTION

It is an object of the present invention to provide a ferroelectric memory which ensures a high reliability without increasing the area of a capacitor, and a method of manufacturing the same.

The present invention provides a ferroelectric memory which includes a semiconductor substrate formed with a circuit including a transistor for memory cell selection, an interlayer insulating film formed on the semiconductor substrate, a storage element comprised of a ferroelectric capacitor formed on the interlayer insulating layer at a position corresponding to a diffusion layer of the transistor, and a cell plug for electrically connecting said diffusion layer with the ferroelectric capacitor. The cell plug is an electrically conductive material filled in a contact hole formed through the interlayer insulating film, wherein the contact hole is formed to be wider toward the ferroelectric capacitor and narrower toward the diffusion layer.

In the present invention, the contact hole is formed to be wider toward the ferroelectric capacitor and narrower toward the diffusion layer. With this contact hole, when the cell plug is formed by filling the contact hole with an electrically conductive material such as tungsten, it is possible to prevent a vertical void, or “tungsten seam,” in a central region of the cell plug. Consequently, since the surface of the cell plug can be finished to be flat when the tungsten and the like are polished, the characteristics are not degraded in a lower electrode of the ferroelectric capacitor formed on the cell plug. Accordingly, the lower electrode thickness may be reduced result in a higher reliability.

### BRIEF DESCRIPTION OF THE DRAWINGS

FIG. 1 is a cross-sectional view schematically showing the structure of a laminated ferroelectric memory according to a first embodiment of the present invention;

FIG. 2 is a cross-sectional view schematically showing the structure of a conventional laminated ferroelectric memory;

FIGS. 3(a) to 3(c) are explanatory diagrams showing problems of the conventional cell plug;

FIGS. 4(a) to 4(d) are process diagrams showing a main portion of the laminated ferroelectric memory of FIG. 1 in a method of manufacturing the same;

FIGS. 5(a) to 5(e) are process diagrams showing a method of forming a cell plug 20 in FIG. 1;

FIGS. 6(a) to 6(f) are process diagrams showing a method of forming a cell plug according to a second embodiment of the present invention; and

FIGS. 7(a) to 7(d) are process diagrams showing a method of forming a cell plug according to a third embodiment of the present invention.

### DETAILED DESCRIPTION OF THE INVENTION

After an interlayer insulating film is formed on a circuit surface of a semiconductor substrate formed with a circuit including a transistor for storage element selection, a contact hole is formed through the interlayer insulating film by a plasma etching method using an etching gas including CHF₃. Next, the contact hole is filled with an electrically conductive material such as tungsten to form a cell plug. Subsequently, a lower electrode, a ferroelectric film, and an upper electrode of the ferroelectric capacitor are formed in sequence.

The foregoing and other objects and novel features of the present invention will become more fully apparent from the following description of the preferred embodiment when read in conjunction with the accompanying drawings. The drawings, however, are presented exclusively for purposes of description, and are not intended to limit the scope of the invention.

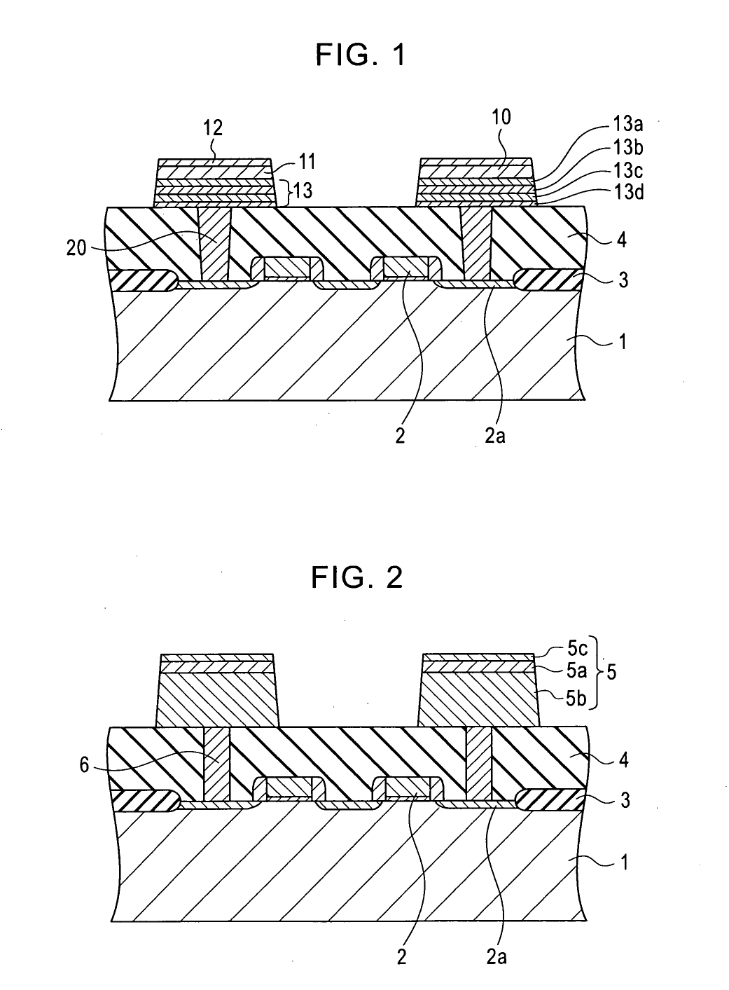

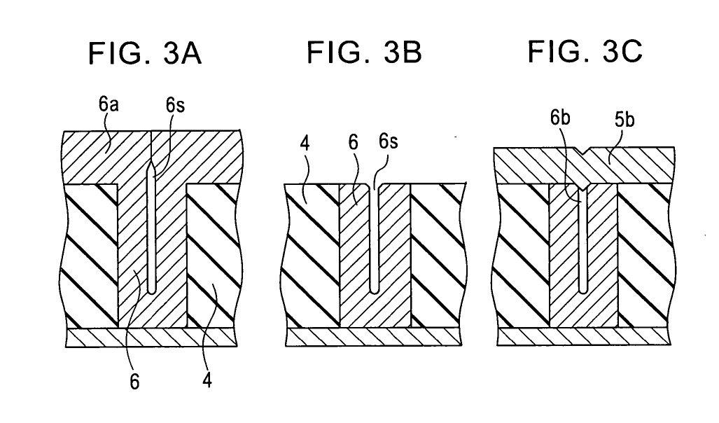

FIG. 1 is a cross-sectional view schematically showing the structure of a laminated ferroelectric memory according to a first embodiment of the present invention, wherein elements common to those in FIG. 2 are designated the same reference numerals.

This laminated ferroelectric memory has a transistor 2 for selection and an element separation region 3 formed on the surface of a semiconductor substrate 1. An interlayer film 4 is formed over the entire surface of the semiconductor substrate 1 including these transistor 2 and element separation region 3, and a ferroelectric capacitor 10, which is a storage element, is disposed on the interlayer insulating film 4.

The ferroelectric capacitor 10 has a ferroelectric film 11 formed of crystallized SBT, and an upper electrode 12 made of Pt is formed on the upper side of the ferroelectric film 11. Formed on the lower side of the ferroelectric film 11 is a laminated lower electrode 13 which is composed of a Pt layer 13a, an IrO (iridium oxide) layer 13b, an Ir (iridium) layer 13c, and TiAlN (titanium aluminum nitride) layer 13d laminated in sequence. The ferroelectric layer 11 has a thickness of approximately 120 nm; the upper electrode 12, Pt layer 13a, IrO layer 13b, and Ir layer 13c approximately 100 nm; and the TiAlN layer 13d approximately 50 nm.

The lower electrode 13 of the ferroelectric capacitor 10 is connected to a diffusion layer 2a of the transistor 2 through a cell plug 20 made of tungsten and formed in the interlayer insulating film 4. The cell plug 20 has an average diameter of approximately 0.6 μm, and is tapered such that it is thicker toward the ferroelectric capacitor 10 and is thinner toward the transistor 2.

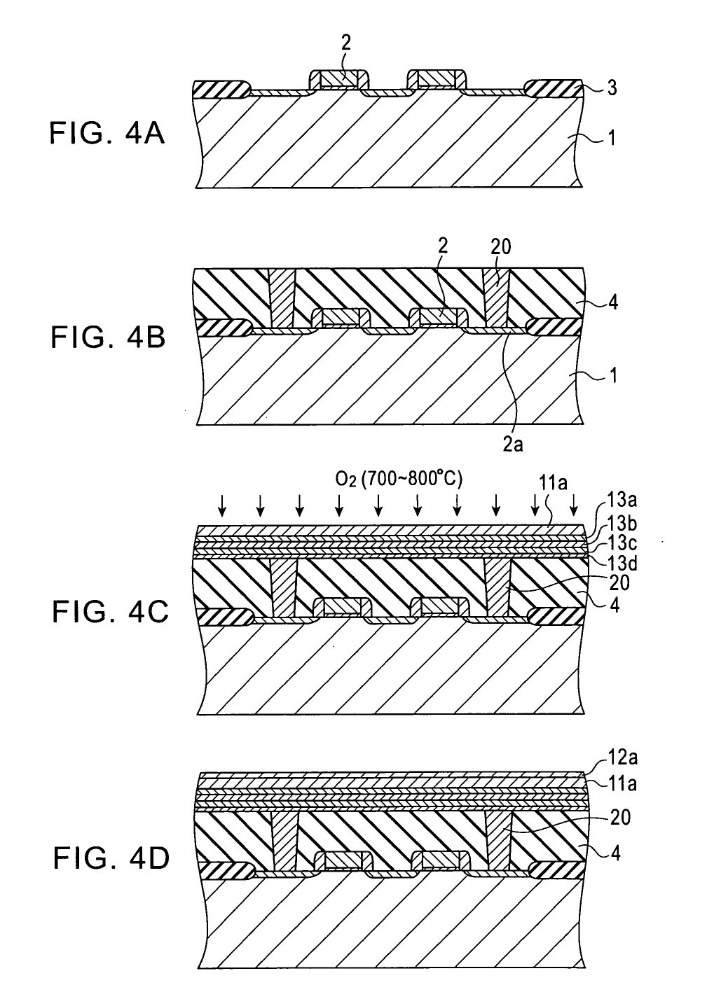

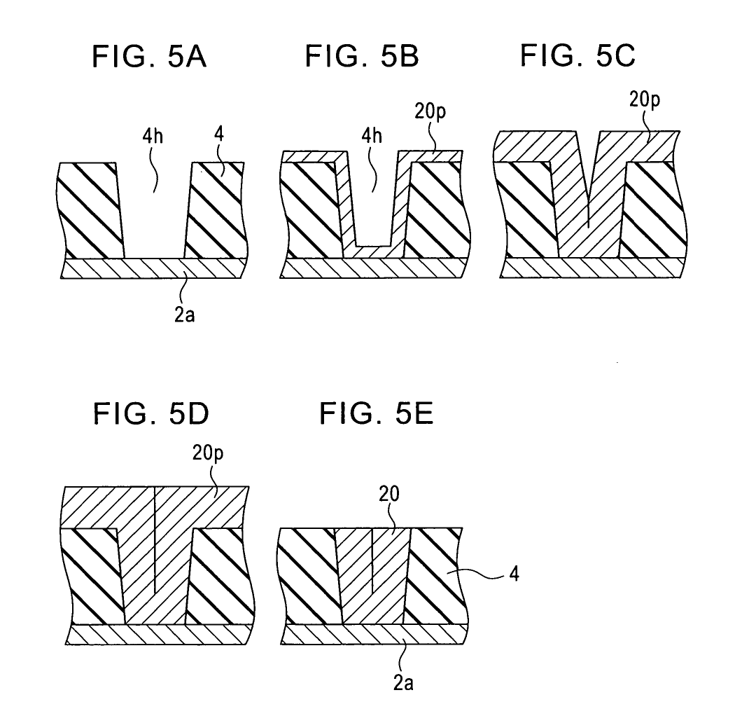

FIGS. 4(a) to 4(d) are process diagrams showing a main portion of the laminated ferroelectric memory of FIG. 1 in a method of manufacturing the same, and FIGS. 5(a) to 5(e) are process diagrams showing a method of forming the cell plug 20 in FIG. 1. In the following, a method of manufacturing the ferroelectric memory shown in FIG. 1 will be described with reference to FIGS. 4 and 5.

(1) Step 1

As shown in FIG. 4(a), a circuit including the transistor 2 and element separation region 3 is formed on the surface of the semiconductor substrate 1 in a normal wafer step.

(2) Step 2

The interlayer insulating film 3 is formed over the entire surface of the circuit formed in Step 1, and the surface of the interlayer insulating film 4 is planarized by a CMP method.

(3) Step 3-1

A contact hole 4h is formed in the interlayer insulating film 4 above the diffusion layer 2a of the transistor 2 formed in Step 2 for embedding a cell plug, as shown in FIG. 5(a). The contact hole 4h is formed by plasma etching using an etching gas including CHF₃ under a condition in which deposits are readily formed on a side wall of the contact hole 4h during the processing. Therefore, more deposits are formed on the side wall as the etching progresses, so that the diameter of the contact hole 4h is reduced more toward the bottom of the contact hole 4h, resulting in the tapered contact hole 4h as shown.

(4) Step 3-2

Next, though not shown, a barrier film made of TiN or Ti/TiN is formed in order to prevent a reaction of the diffusion layer 2a with the tungsten which is the material of the cell plug. For forming the barrier layer to maintain the tapered shape, a CVD method is preferably used. However, the formation is not limited to the use of the CVD method as long as sufficient coverage is ensured and the contact hole profile is not deformed too much. A heat treatment is performed as required in order to stabilize the barrier film.

(5) Step 3-3

Next, tungsten is filled in the contact hole 4h by a CVD method. For forming a tungsten film within the tapered contact hole 4h with a wider opening by the CVD method, a generation gas is sufficiently supplied deep into the contact hole 4h up to the bottom. In this way, a tungsten film 20p is orderly formed the bottom of the contact hole 4h, as shown in FIGS. 5(b), 5(c), 5(d), without seam.

(6) Step 3-4

After the contact hole 4h has been filled with tungsten which will later serve as a cell plug 20, and the surface of the interlayer insulating film 4 has been covered with tungsten, the tungsten film 20p is polished by a CMP method to remove the tungsten film 20p on a flat region. Consequently, as shown in FIGS. 5(e) and 4(b), the surface of the interlayer insulating film 4 and the top of cell plug 20 are exposed. The top of the cell plug 20 forms a smooth flat surface because it is free of seam.

(7) Step 4

A TiAlN layer 13d, an Ir layer 13c, an IrO layer 13b, and a Pt layer 13a, all made of electrically conductive materials, which make up the lower electrode 13 of the ferroelectric capacitor 10, are vapor deposited in sequence over the entire surface of the interlayer insulating film 4 embedded with the cell plug 20, as produced through Step 3-1 to Step 3-4. Further, an SBT layer 11a, which will later serve as the ferroelectric film 11, is formed on the surface of the Pt layer 13a of the lower electrode 13. Subsequently, a heat treatment is performed in an oxygen atmosphere at temperatures of 700 to 800° C. for crystallizing the overlying SBT surface 11a, as shown in FIG. 4(c).

(8) Step 5

A Pt film 12a, which will later serve as the upper electrode 12, is vapor deposited on the surface of the crystallized SBT layer 11a, as shown in FIG. 4(d).

Subsequently, the SBT layer 11a, as well as the Pt layer 12a and Pt layer 13a to TiAlN layer 13d, which sandwich the SBT layer 11a, are patterned for separation into individual ferroelectric capacitors 10 corresponding to respective cell plugs 20. Then, a heat treatment is also performed for recovering the ferroelectric capacitor 10 from damages applied thereto from the side surface during the patterning. Conditions for this heat treatment are similar to those of the heat treatment for crystallizing the SBT layer 11a. In this way, a laminated ferroelectric memory is completed, as shown in FIG. 1.

As described above, the laminated ferroelectric memory according to the first embodiment has the tapered cell plug 20 which is wider toward the opening and narrower toward the bottom. Therefore, when the cell plug 20 in such a shape is formed of tungsten using a CVD method, the top of the cell plug can be formed to have a smooth flat surface without seam in a central region of the cell plug 20. In this way, the lower electrode 13 of the ferroelectric capacitor 10 can be formed in a uniform and flat shape on the cell plug 20 without crack or fracture. Consequently, the lower electrode thickness may be reduced because it does not need to make up for the seam on the surface of the cell plug. Thus, the resulting ferroelectric memory advantageously can achieve a high reliability without increasing the area of the capacitor.

While SBT is used for the ferroelectric material; Pt for the electrodes; and tungsten for the cell plug in the foregoing embodiment, the materials are not limitations to the present invention.

Also, while the contact hole is formed using the plasma etching method with a gas including CHF₃, any gas may be used as long as it produces similar effects. Alternatively, a wet etching method may be used instead using a liquid chemical such as OKI-P acid or the like.

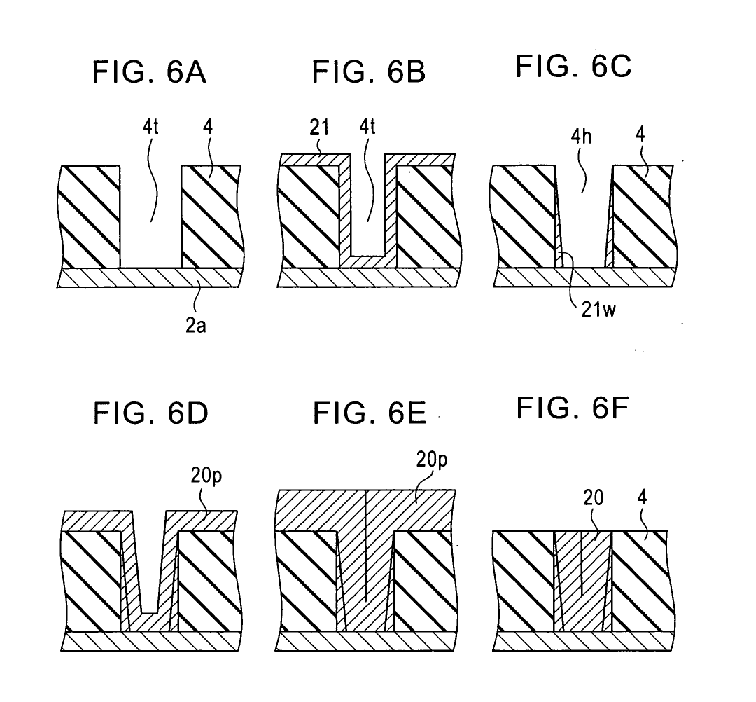

FIGS. 6(a) to 6(f) are process diagrams showing a method of forming a cell plug according to a second embodiment of the present invention. This method of forming a cell plug is substituted for Step 3-1 to Step 3-4 (i.e., in FIG. 5) in the first embodiment.

First, as shown in FIG. 6(a), a cylindrical contact hole 4t, not tapered, is formed in the interlayer insulating film 4 by a method similar to the prior art.

Next, as shown in FIG. 6(b), an oxide film (or nitride film) 21 is formed over the entire wafer. In this event, a CVD method is preferably used to form the film 21 in a uniform thickness over the entire wafer.

Further, the oxide film 21 is fully etched back for removal. In this event, part of the oxide film 21 remains as a side wall 21w on the side surface of the contact hole 4h. This result in the formation of the tapered contact hole 4h which is wider toward the opening and narrower toward the bottom, as shown in FIG. 6(c).

Subsequent steps are similar to Step 3-3, Step 3-4 in the first embodiment, wherein tungsten is filled by a CVD method to conformally form a tungsten film 20p from the bottom of the contact hole 4h, resulting in the formation of the seam-free tungsten film 20p within the contact hole 4h and the surface of the interlayer insulating film 4. Further, as the tungsten film 20p on the surface of the interlayer insulating film 4 is polished by a CMP method for removal, the top of the cell plug 20 exposes as a smooth flat surface without seam, as shown in FIG. 6(f).

As described above, the method of forming a cell plug according to the second embodiment first forms the cylindrical contact hole 4t, and forms the side wall 21w within the contact hole 4t to form the contact hole 4h which is wider toward the opening and narrower toward the bottom. In this way, when the tapered contact hole 4h is filled with tungsten to form the cell plug 20, the resulting cell plug 20 advantageously has a smoothly flat head without seam in a central region thereof.

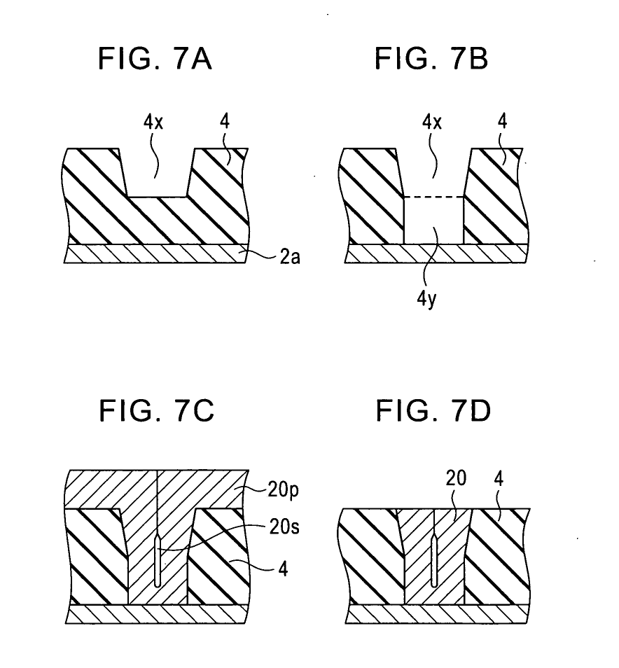

FIGS. 7(a) to 7(d) are process diagrams showing a method of forming a cell plug according to a third embodiment of the present invention. Similar to the second embodiment, this method of forming a cell plug is performed in place of Step 3-1 to Step 3-4 (i.e., in FIG. 5) in the first embodiment.

First, a tapered contact hole 4x is formed up to an intermediate position at an arbitrary depth from the surface of the interlayer insulating film 4 by plasma etching using an etching gas including CHF₃, as shown in FIG. 7(a).

Subsequently, a vertical contact hole 4y having a substantially uniform inner diameter is formed through the remaining insulating film 4 by plasma etching using an etching gas including C₄F₈, as shown in FIG. 7(b).

Subsequent steps are similar to Step 3-3, Step 3-4 in the first embodiment, wherein tungsten is filled by a CVD method to form a tungsten film 20p from the bottom of the contact holes 4x, 4y, as shown in FIG. 7(c). In this event, while a seam 20s may occur in a central region of the non-tapered contact hole 4y, the tapered contact hole 4x is filled with the seam-free tungsten film 20p. Further, as the tungsten film 20p on the surface of the interlayer insulating film 4 is polished by a CMP method for removal, the exposed head of the resulting cell plug 20 has a smooth flat surface without seam.

As described above, the method of forming a cell plug according to the third embodiment forms the tapered contact hole 4x in an upper portion. Thus, when the contact holes 4x, 4y are filled with tungsten to form the cell plug 20, no seam will occur at least in the tapered portion of the cell plug 20, so that the resulting cell plug 20 can advantageously have the head formed with a smooth flat surface.

This application is based on a Japanese patent application No. 2004-263279 which is incorporated herein by reference.

What is claimed is:

1. A ferroelectric memory comprising:
a semiconductor substrate formed with a circuit including a transistor for memory cell selection;
an interlayer insulating film formed on a circuit surface of said semiconductor substrate;
a storage element comprised of a ferroelectric capacitor formed on said interlayer insulating layer at a position corresponding to a diffusion layer of said transistor; and
a cell plug for electrically connecting said diffusion layer with said ferroelectric capacitor through an electrically conductive material filled in a contact hole formed through said interlayer insulating film,
wherein said contact hole is formed to be wider toward said ferroelectric capacitor and narrower toward said diffusion layer.

2. A ferroelectric memory according to claim 1, wherein said contact hole is formed to be gradually narrower from the ferroelectric capacitor to the diffusion layer.

3. A ferroelectric memory according to claim 1, wherein said contact hole is formed to be gradually narrower from the ferroelectric capacitor to an intermediate position toward said diffusion layer, and to have a uniform width from the intermediate position to the diffusion layer.

4. A method of manufacturing a ferroelectric memory comprising a semiconductor substrate formed with a circuit including a transistor for memory cell selection, an interlayer insulating film formed on a circuit surface of said semiconductor substrate, a storage element comprised of a ferroelectric capacitor formed at a position on said interlayer insulating layer corresponding to a diffusion layer of said transistor, and a cell plug for electrically connecting said diffusion layer with said ferroelectric capacitor through an electrically conductive material filled in a contact hole formed through said interlayer insulating film,
said method comprising the steps of:
forming said interlayer insulating film on a circuit surface of said semiconductor substrate; and
forming said contact hole through said interlayer insulating film by a plasma etching method using an etching gas which include CHF₃.

5. A method of manufacturing a ferroelectric memory comprising a semiconductor substrate formed with a circuit including a transistor for memory cell selection, an interlayer insulating film formed on a circuit surface of said semiconductor substrate, a storage element comprised of a ferroelectric capacitor formed at a position on said interlayer insulating layer corresponding to a diffusion layer of said transistor, and a cell plug for electrically connecting said diffusion layer with said ferroelectric capacitor through an electrically conductive material filled in a contact hole formed through said interlayer insulating film,
said method comprising the steps of:
forming said interlayer insulating film on the circuit surface of said semiconductor substrate;
forming a first contact hole from the ferroelectric capacitor side to the intermediate position in said interlayer insulating film by a plasma etching method using an etching gas including CHF₃; and
forming a second contact hole from the intermediate position to the diffusion layer side by a plasma etching method using an etching gas including C₄F₄.

6. A method of manufacturing a ferroelectric memory comprising a semiconductor substrate formed with a circuit including a transistor for memory cell selection, an interlayer insulating film formed on a circuit surface of said semiconductor substrate, a storage element comprised of a ferroelectric capacitor formed at a position on said interlayer insulating layer corresponding to a diffusion layer of said transistor, and a cell plug for electrically connecting said diffusion layer with said ferroelectric capacitor through an electrically conductive material filled in a contact hole formed through said interlayer insulating film,
said method comprising the steps of:
forming said interlayer insulating film on a circuit surface of said semiconductor substrate;
forming a cylindrical throughhole through said interlayer insulating film by a plasma etching method using an etching gas including C₄F₈;
forming an oxide film or an nitride film on the surface of said interlayer insulating film including a wall surface of said throughhole; and
etching back said oxide film or nitride film to leave a side wall on the wall surface of said throughhole,
wherein said steps are sequentially executed to form said contact hole.
